(19) United States
(12) Patent Application Publication
(10) Pub. No.: US 2009/0111046 A1
(43) Pub. Date: Apr. 30, 2009

(54) Direct laser and ultraviolet lithography of porous silicon photonic crystal devices

(76) Inventors: Heungmann Park, Nashville, TN (US); James H. Dickerson, Nashville, TN (US); Alex A. Stramel, Fayetteville, AR (US); David A. Harju, Franklin, TN (US); Sharon M. Weiss, Nashville, TN (US)

Correspondence Address: JOHN BRUCKNER, P.C., P.O. BOX 490, FLAGSTAFF, AZ, 86002, US

(21) Appl. No.: 12/228,430

(22) Filed: Aug. 11, 2008

Related U.S. Application Data
(60) Provisional application No. 60/964,313, filed on Aug. 10, 2007.

(51) Int. Cl. G03F 7/004

(52) U.S. Cl. 430/270.1

(57) ABSTRACT

We have developed a simple method to locally change the optical properties of porous silicon multilayers and photonic crystal architectures. This technique allows for the direct photolithography of porous silicon multilayers, heterostructures, and photonic crystals. The procedure controls the local oxidation within the porous silicon layers via ultraviolet radiation or via high intensity laser beam (λ=532.8 nm) exposure. Subsequently, immersion of the non-irradiated and irradiated regions of the porous silicon heterostructures within an alcohol solvent (for example, methanol and ethanol) induces either a marked degradation or no degradation, respectively, in the optical properties of the material. This direct, optical lithographic technique may have significant use in the production of silicon-based optical and opto-electronic devices for laser, optical computation, telecommunications, and other applications. Potential devices include patternable porous silicon waveguides, optical filter, optical switches, and photonic band-gap structures.

### CROSS-REFERENCE(S) TO RELATED APPLICATION(S)

This application claims a benefit of priority under 35 U.S.C. 119(e) from copending provisional patent application U.S. Ser. No. 60/964,313, filed Aug. 10, 2007, the entire contents of which are hereby expressly incorporated herein by reference for all purposes.

### BACKGROUND INFORMATION

### Field of the Invention

Embodiments of the invention relate generally to the field of direct laser and ultraviolet lithography of porous silicon photonic crystal devices.

### SUMMARY OF THE INVENTION

There is a need for the following embodiments of the invention. Of course, the invention is not limited to these embodiments.

According to an embodiment of the invention, a process comprises: _. According to another embodiment of the invention, a machine comprises: _. According to another embodiment of the invention, a manufacture comprises: _. According to another embodiment of the invention, a composition of matter comprises: _.

These, and other, embodiments of the invention will be better appreciated and understood when considered in conjunction with the following description and the accompanying drawings. It should be understood, however, that the following description, while indicating various embodiments of the invention and numerous specific details thereof, is given for the purpose of illustration and does not imply limitation. Many substitutions, modifications, additions and/or rearrangements may be made within the scope of an embodiment of the invention without departing from the spirit thereof, and embodiments of the invention include all such substitutions, modifications, additions and/or rearrangements.

### BRIEF DESCRIPTION OF THE DRAWINGS

The drawings accompanying and forming part of this specification are included to depict certain embodiments of the invention. A clearer concept of embodiments of the invention, and of components combinable with embodiments of the invention, and operation of systems provided with embodiments of the invention, will be readily apparent by referring to the exemplary, and therefore nonlimiting, embodiments illustrated in the drawings (wherein identical reference numerals (if they occur in more than one view) designate the same elements). Embodiments of the invention may be better understood by reference to one or more of these drawings in combination with the following description presented herein. It should be noted that the features illustrated in the drawings are not necessarily drawn to scale.

FIG. 1 illustrates the first sample obtained by laser illumination and its stop-band structure and its photonic band structures, representing an embodiment of the invention.

FIG. 2 illustrates a procedure of the lithography experiment and a sample by V-shaped mask, representing an embodiment of the invention.

FIGS. 3A-3B illustrate (a) a sample on glass substrate and (b) a sample on silicon substrate, representing an embodiment of the invention.

FIG. 4 illustrates a Scanning electron microscope image of a cross-section of a porous silicon heterostructure; the red line marks the interface between the masked (left) and unmasked (right) portions of the structure; there exists no evidence of layer degradation in the image, representing an embodiment of the invention.

### DESCRIPTION OF PREFERRED EMBODIMENTS

Embodiments of the invention and the various features and advantageous details thereof are explained more fully with reference to the nonlimiting embodiments that are illustrated in the accompanying drawings and detailed in the following description. Descriptions of well known starting materials, processing techniques, components and equipment are omitted so as not to unnecessarily obscure the embodiments of the invention in detail. It should be understood, however, that the detailed description and the specific examples, while indicating preferred embodiments of the invention, are given by way of illustration only and not by way of limitation. Various substitutions, modifications, additions and/or rearrangements within the spirit and/or scope of the underlying inventive concept will become apparent to those skilled in the art from this disclosure.

We have developed a technique to process photolithographically porous silicon heterostructures and photonic crystal architectures, using laser and ultraviolet light exposure and a subsequent alcoholic bath treatment. This technique would be the first method to process directly the optical properties of porous silicon multilayers, heterostructures, and photonic crystal architectures.

We have developed a technique to produce and to inhibit the transformation of the optical properties of porous silicon multilayers and photonic crystal architectures via a two step procedure. This technique allows for the direct photolithography of porous silicon multilayers and photonic crystals. The procedure involves the promotion of surface oxidation within the porous silicon layers via ultraviolet radiation or via high intensity laser beam (λ=532.8 nm) exposure. Subsequently, exposure of the non-irradiated and irradiated regions of the porous silicon heterostructures to an alcohol solvent (methanol, ethanol, butanol, or isopropanol) induces either a marked degradation or no degradation, respectively, in the optical properties of the material.

Although local oxidation effects, due to alcohol and heat, have been documented for porous silicon monolayers, there has been no report on the use of light or solvent to induce changes in the optical properties of porous silicon multilayers, heterostructures, or photonic crystal device architectures. This direct, optical lithographic technique may have significant use in the production of silicon-based optical and opto-electronic devices for laser, optical computation, telecommunications, and other applications. Potential devices include patternable porous silicon waveguides, optical filter, optical switches, and photonic stop-band structures.

### Procedure for Photonic Stop-Band Lithography on Porous Silicon.

### Preparation of the Porous Silicon Photonic Crystal.

The first procedural step taken to produce porous silicon thin films was to cleave silicon wafers into manageable and appropriate sample sizes. The silicon wafer samples were cleaved from the wafers into approximately 2.5 cm by one 2.5 cm samples. The wafers used for the entirety of the stated experiments were P-type, boron doped wafers with resistivity between 0.01 and 0.02 Ωcm, ten cm diameter, thickness between 500 and 550 microns, <100> orientation, with only one side highly polished. Entire wafers were cleaved into samples at a single time and stored for experimental use. The samples were placed separately in plastic, partitioned Petri dishes at room temperature, stored from one day up to several months.

The next procedural step taken was to clean thoroughly the silicon samples to remove any dust or debris from the surfaces of the sample. This step involved securing a corner of the sample with tweezers and rinsing both sides of the sample with approximately five mL of ethanol. The sample was held at a downward angle to let the ethanol flow downward off the face of the sample. The ethanol was continually applied to the face of the sample with a squirt bottle, starting at the uppermost part of the sample, and then moving back and forth down the face of the sample to use the downward flow of ethanol to carry any debris off of the sample face. This was done for each side of the sample.

Immediately after rinsing both sides of the silicon sample with ethanol, the sample was dried with nitrogen gas. This was accomplished by applying a pure stream of nitrogen gas approximately five cm normal to the surface of the sample until one side of the sample was visibly dry, then drying the other side in the same fashion. The sample was secured during the drying process with tweezers much in the same way as in the rinsing process described above.

After the sample was rinsed and dried, the sample was placed flat, polished side up, roughly centered onto a silver plate approximately five cm wide by ten cm long. Next, a rubber O-ring with diameter approximately two cm was roughly centered on the top of the silicon sample. Next, the silver plate with silicon sample and O-ring on top was placed onto the base of the etching cell. The base of the etching cell is comprised of a solid piece of Teflon approximately 15 cm wide by ten cm long and two cm thick with four threaded, steel bolts protruding up through the Teflon base. The Teflon base lies flat, and the bolts protrude up through the Teflon and extend approximately eight cm above the Teflon base, normal to the Teflon base's surface. The bolts are arranged in a square pattern, each at a respective corner, spaced approximately seven cm apart. This allows enough space for the silver plate to lay flat on the Teflon base in between the steel bolts without touching the bolts themselves.

Once the silicon sample was placed on the silver plate on the base of the etching cell and the rubber O-ring was placed on top of the silicon sample, the top of the etching cell was placed on top of the silicon sample and rubber O-ring. The top of the etching cell is also made of Teflon; however it is circular and shaped like a cylinder with one end closed. The outer surface of cylindrical part of the etching cell is approximately 12 centimeters in diameter, and the inner surface is approximately 9 centimeters in diameter. Therefore the cylindrical walls are thick enough to have holes bored over the length of the walls to accept the four steel bolts attached to the base of the etching cell. The Teflon cylinder is closed at the bottom face, machined out of a single piece of Teflon, leaving only the top face of the cylinder open. However, a small hole exists in this bottom face of the cylinder, centered in the middle of the circular bottom face. This hole is approximately 1.5 centimeters in diameter, and is beveled to accept the rubber O-ring on the underside. The top piece of the etching cell is placed on top of the base of the etching cell by sliding the steel bolts through the holes in the cylindrical top portion of the etching cell. The silicon sample is then pressed in between the silver plate on the bottom side, which rests on the Teflon base piece of the etching cell, and the rubber O-ring, which fits snuggly in the bevel of the top Teflon portion of the etching cell.

The next procedural step taken was to place the electrode into the top portion of the etching cell and secure the electrode. The electrode is made of a platinum wire arranged in a spiral pattern with diameter approximately five cm. The wire extends up and out of the etching cell for electrical contact. Next, a ring shaped brass bracket is placed onto the top portion of the etching cell, securing the platinum electrode between the top Teflon portion of the etching cell and the brass bracket by using four brass nuts that tighten against the steel bolts, forcing the arrangement downward. Brass nuts are screwed onto the steel bolts attached to the base of the etching cell to force the top portion of the etching cell down, firmly pressing each adjacent piece together and creating a tight seal where the rubber O-ring is.

The final procedural step taken to set up the etching cell was to attach the power source to the silver plate which is the cathode, and the platinum wire, the anode.

### Etching Process.

After the silicon sample was placed in the etching cell, the etching of the silicon could begin. The first step in the etching process was to place 20 to 30 mL of hydrofluoric acid-based electrolyte into the etching cell. The electrolyte was 15% hydrofluoric acid (HF) in ethanol. 20 to 30 mL of electrolyte was enough to adequately submerge the spiral portion of the platinum anode by one to two mL and provide enough acid to fuel adequately all of the chemical processes taking place throughout the etching process. The electrolyte was contained by the upper Teflon portion of the etching cell, only exposing the silicon showing through the hole in the bottom face of the cylindrical portion of the etching cell. The rubber O-ring being pressed between the silicon sample and the upper portion of the etching cell created a liquid tight seal, therefore containing the electrolyte.

Once the acid was added to the etching cell and the platinum anode and silver cathode were attached to the power source using simple alligator clips, the etching could commence. The porous silicon optical device was created by applying specific currents for given amounts of time. The currents were supplied to the platinum anode and silver cathode to etch the silicon by means of a power source. The specific currents and lengths of time the currents were applied by the power source were controlled through a Labview program that controlled the power source very precisely. According to simulated and previous experimental results, several stages of specific currents and corresponding lengths of time that those currents should be applied were entered into the program, and when the sample was ready, the program would go through the series of steps to produce the porous silicon optical device. Several different porous silicon optical devices were made into thin film samples, many made with different conditions in terms of currents and times.

### Thin Film Lift Off Process.

After the porous silicon optical device was created, the porous silicon optical device could be lifted off as a thin film. This was done by applying much higher currents than typically used during the creation process of the optical device. Once the program to create the porous silicon optical device ended, new current and time parameters were entered into the Labview program to lift off the etched portion from the bulk silicon. This reentering of parameters into the program took approximately one to two minutes after the completion of the creation of the optical device, however was a variable process and therefore could not be added as an extra static step at the end of the optical device creation process.

The first step in the lift off process was to apply two current pulses of 500 mA for 1.7 seconds with a 1.7 second delay in between. This step was always consistent. Next, 420 mA current pulses for 1.5 seconds were applied between 8 and 12 times with a 6 second delay in between pulses. A delay of approximately 1 minute was required in between these two sections of the lift off process due to entering new values into the Labview program. After the 8 to 12 current pulses of 420 mA were applied, the sample was visually inspected. Without physically changing anything involved with the etching cell, the surface of the silicon sample exposed to the acid could be observed. According to the fraction of the surface of the silicon that appeared loosened by the previous current pulses, a new amount of current pulses at 420 mA for 1.5 seconds with 6 second delays were applied. Typically one quarter to one half of the silicon sample appeared loosened after the initial 8 to 12 pulses. According to how much of the sample appeared loosened a new value typically between 8 and 4 current pulses was decided upon and applied following the same amperage, time, and delay time. After each additional phase of current pulses, the sample was visually inspected. Current pulses were applied until the whole sample appeared loosened, which could be described as though the visible, circular portion of the silicon sample formed a smooth dome, whereas the sample was flat before the high current pulses. Typically samples experienced between 12 and 35 current pulses at 420 mA.

### Thin Film Transfer Process.

Once the sample was visible ready, the acid was carefully removed from of the etching cell with a pipette. The sample and etching cell were carefully rinsed with ethanol by squirting enough ethanol onto the side of the Teflon portion of the etching cell to fill the cell with ethanol above the point where the acid made contact. The ethanol was removed with a pipette and the rinsing process was repeated two more times.

Next, the etching cell was disassembled very carefully in the opposite order as it was assembled. The top portion of the etching cell and rubber O-ring were removed, leaving the silicon sample resting on the silver plate. Without moving the silicon sample from the silver plate, the remaining portion of the etched thin film was broken from the bulk using tweezers. The silicon below the thin film was broken free by means of the high current pulses; however the thin film was still attached around the perimeter of the etched region. Therefore, using the tip of very thin, flat edged tweezers and pushing down firmly, normal to the silicon sample's surface around the edge of the circular etched region, the thin film was broken free. The silicon thin film must be broken free around the entire perimeter of the etched region by pushing firmly with the flat edge of the tweezers.

After the thin film was broken free from the substrate, the porous silicon thin film could be transferred onto different substrates like glass, gold, quartz, or others. This was done by filling a standard glass Petri dish with roughly 30 mL of ethanol and placing the substrate into the Petri dish, submerged in the ethanol. Typical a standard three inch by one inch glass microscope slide was used, which is very thin. This was easily submerged by the 30 mL of ethanol that filled the glass Petri dish close to one third high. Next, the silicon thin film sample, which was broken from the substrate yet was still resting on the substrate, was placed into the ethanol filled Petri dish. The silicon sample was secured with tweezers by the substrate and held level as it was transferred to the Petri dish and submerged into the ethanol. Once in the ethanol, the substrate was placed near the glass slide or other desired substrate. The silicon substrate and receiving substrate were typically the same thickness so as to make transfer easy. Using pipettes to create very gentle currents in the ethanol, flowing from the silicon substrate in the direction of the desired substrate, the thin film was lifted by the moving ethanol and moved over the desired substrate. Once the thin film was over the desired substrate, ethanol was very carefully removed from the Petri dish using pipettes, making sure that the thin film remained over the desired substrate. If the thin film moved in the process, it could easily be guided in which ever direction was needed by, again, using a pipette to create a gentle current in the ethanol in the desired direction. Once enough ethanol was removed from the Petri dish, the thin film would make contact with the desired substrate and stick well enough to remove the substrate with tweezers. Careful attention was made to remove the substrate with the porous silicon thin film on top as level as possible so that the still mobile thin film would not slide off the top of the substrate. The substrate with the porous silicon thin film on top was then put into an oven at 100 degrees Celsius for approximately five minutes to evaporate any ethanol.

### Photonic Stop-Band Manipulation Via Methanol

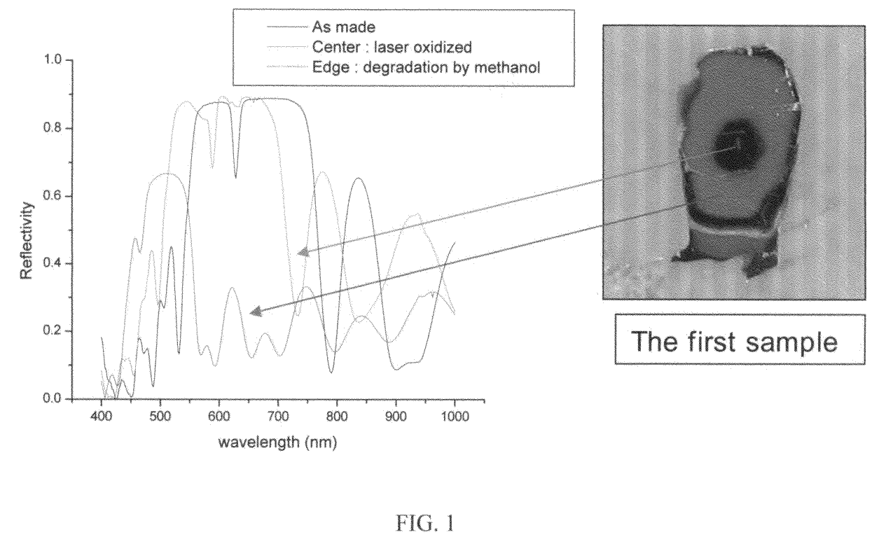

If a fresh sample (a porous silicon sample that is within two weeks of its initial fabrication) is treated by methanol or ethanol, a change in the reflectance magnitude and the short and long wavelength edges of the stop-band is observed. This change is evident visually through a change in the reflection or transmission color and is detected optically through a shift in the reflectance profile (FIG. 1). Old samples (typically more than two months since their initial fabrication) do not exhibit the marked reflectance degradation, induced by the methanol treatment. It is considered that a thick native oxide layer within the porous silicon inhibits the reaction between porous silicon and methanol.

Since the oxidized sample does not exhibit the optical degradation, if we pattern the oxidation on a fresh porous silicon photonic crystal, we can pattern the photonic stop-band of the material. Thus, the invention can include the employment of lasers or ultraviolet sources, in conjunction with alcohol immersion treatments, to affect the optical properties of porous silicon heterostructures and photonic crystals. The local patterning of the porous silicon structure was achieved by direct writing onto the material with focused laser beam (λ=532.8 nm) or by illuminating the material with an intense ultraviolet light or a laser beam with an overlying photomask.

The first sample, seen in FIG. 1, was obtained by direct illumination of a 532.8 nm laser beam onto a porous silicon microcavity sample immersed in methanol. Before conducting the experiment, the sample's reflectivity was measured. The stop-band extended from 550 nm (yellow) to 750 nm (red); thus, the microcavity primarily reflects yellow, orange and red wavelengths (black curve in FIG. 1). The spectra of the sample after receiving the photolithographic treatment (detailed in the following sections) is also shown in FIG. 1, where the laser irradiated region is represented by the red curve (optical properties retained) and the non-irradiated region is represented by the green curve (degradation).

### Experimental Procedure for Photonic Stop-Band Lithography of Porous Silicon Heterostructures and Photonic Crystals

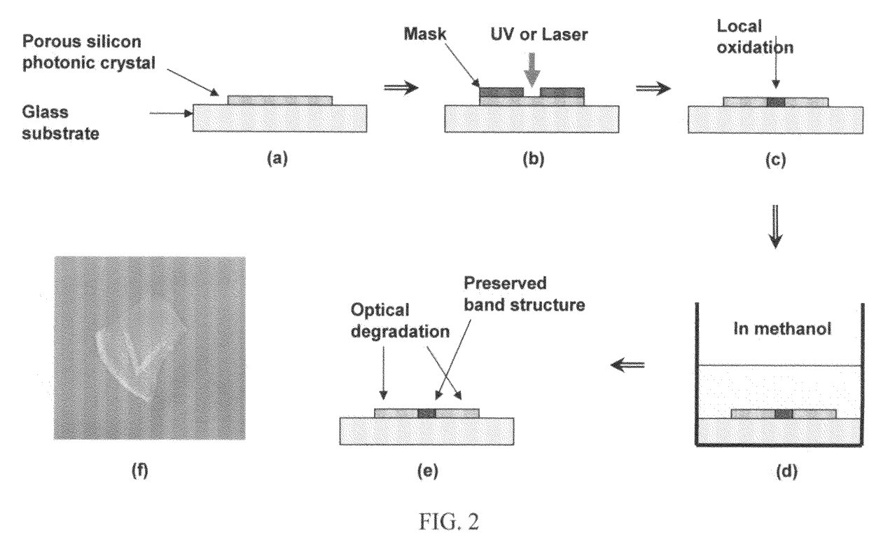

FIGS. 2A-2F provides a schematic of the procedure to produce photonic stop-band lithography on porous silicon heterostructures and photonic crystals. Referring to FIG. 2A, a porous silicon photonic crystal is prepared on a glass substrate, as described above. The experiment also can be performed on the original silicon substrate from which the porous silicon structure was initially produced.

Referring to FIGS. 2B-2C, a photomask is placed on the porous silicon film. Next, an intense UV light beam or laser beam is illuminated onto the sample. Our experiment employed a mercury UV lamp, with a focused spot intensity of 27 mW/cm², and 532.8 nm laser beam, with a focused spot intensity of 2.0 W/cm². When the mercury lamp was used, at least twenty-three hours was required to produce a clear pattern. Five hours was required for the 532.8 nm laser. It is expected that if UV laser is used we can reduce the illumination time significantly since porous silicon has strong absorption in UV light.

Referring to FIG. 2D, after the illumination, the sample is soaked in methanol. The samples remained immersed in the methanol for at least 48 hours This time constraint on the methanol immersion applied for all free standing, porous silicon heterostructure and photonic crystal samples, which were lifted off from the original silicon substrate. A similar, methanol-induced lithographic phenomenon was observed for porous silicon heterostructures and photonic crystals that were not removed from the original silicon substrate. The required methanol immersion time for such samples significantly increased to at least 10 days. This dramatic increase is attributed to the required time for the methanol to penetrate the entirety of the porous silicon sample architecture.

Referring to FIG. 2E, it can be appreciated that a patterned photonic stop-band structure can be seen. The stop-band for the locally oxidized area (red curve in FIG. 1) is slightly shifted to shorter wavelengths compared to its original spectral position. However, the non-oxidized area has a stop-band whose reflectance magnitude has substantially degraded and whose wavelength range has markedly narrowed and blue-shifted (green curve in FIG. 1).

Referring to FIG. 2F, the unmasked area (V shaped) shows the preserved stop-band, whereas the masked region exhibits the strongly blue-shifted reflectance.

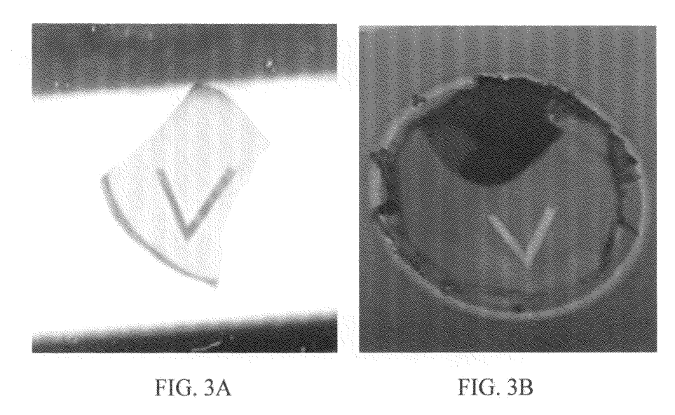

FIG. 3A shows a sample on glass substrate. FIG. 3B shows a sample on silicon substrate. High current was applied to lift the sample off from the silicon substrate.

We have confirmed that the observed changes in the reflectance of the porous silicon heterostructures are not due to a large structural change or a collapse in the porous silicon multilayer. Scanning electron microscope (SEM) images of the porous silicon heterostructure, taken after the alcohol treatment, show no degradation of the sample due to the treatment.

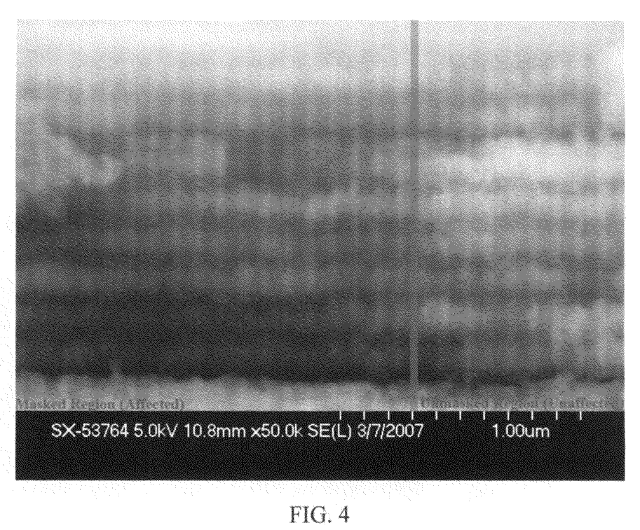

FIG. 4 provides a SEM cross-section image of a porous silicon heterostructure sample. The red (vertical) line (approximately ⅓ from the right edge) in the image represents the interface between the affected (masked) region on the left and the unaffected (unmasked) region on the right. This verifies that the changes in the optical properties of the materials are not due to structural degradation or transformation.

Spatial resolution may be a challenge for defining complicated structures and porous silicon losses may inhibit some applications.

Embodiments of the invention can be cost effective and advantageous for at least the following reasons. Embodiments of the invention improve quality and/or reduce costs compared to previous approaches.

### DEFINITIONS

The term substantially is intended to mean largely but not necessarily wholly that which is specified. The term approximately is intended to mean at least close to a given value (e.g., within 10% of). The term generally is intended to mean at least approaching a given state. The term coupled is intended to mean connected, although not necessarily directly, and not necessarily mechanically. The term proximate, as used herein, is intended to mean close, near adjacent and/or coincident; and includes spatial situations where specified functions and/or results (if any) can be carried out and/or achieved. The term distal, as used herein, is intended to mean far, away, spaced apart from and/or non-coincident, and includes spatial situation where specified functions and/or results (if any) can be carried out and/or achieved. The term deploying is intended to mean designing, building, shipping, installing and/or operating.

The terms first or one, and the phrases at least a first or at least one, are intended to mean the singular or the plural unless it is clear from the intrinsic text of this document that it is meant otherwise. The terms second or another, and the phrases at least a second or at least another, are intended to mean the singular or the plural unless it is clear from the intrinsic text of this document that it is meant otherwise. Unless expressly stated to the contrary in the intrinsic text of this document, the term or is intended to mean an inclusive or and not an exclusive or. Specifically, a condition A or B is satisfied by any one of the following: A is true (or present) and B is false (or not present), A is false (or not present) and B is true (or present), and both A and B are true (or present). The terms a and/or an are employed for grammatical style and merely for convenience.

The term plurality is intended to mean two or more than two. The term any is intended to mean all applicable members of a set or at least a subset of all applicable members of the set. The phrase any integer derivable therein is intended to mean an integer between the corresponding numbers recited in the specification. The phrase any range derivable therein is intended to mean any range within such corresponding numbers. The term means, when followed by the term “for” is intended to mean hardware, firmware and/or software for achieving a result. The term step, when followed by the term “for” is intended to mean a (sub)method, (sub)process and/or (sub)routine for achieving the recited result.

The terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. The terms “consisting” (consists, consisted) and/or “composing” (composes, composed) are intended to mean closed language that does not leave the recited method, apparatus or composition to the inclusion of procedures, structure(s) and/or ingredient(s) other than those recited except for ancillaries, adjuncts and/or impurities ordinarily associated therewith. The recital of the term “essentially” along with the term “consisting” (consists, consisted) and/or “composing” (composes, composed), is intended to mean modified close language that leaves the recited method, apparatus and/or composition open only for the inclusion of unspecified procedure(s), structure(s) and/or ingredient(s) which do not materially affect the basic novel characteristics of the recited method, apparatus and/or composition.

Unless otherwise defined, all technical and scientific terms used herein have the same meaning as commonly understood by one of ordinary skill in the art to which this invention belongs. In case of conflict, the present specification, including definitions, will control.

### CONCLUSION

The described embodiments and examples are illustrative only and not intended to be limiting. Although embodiments of the invention can be implemented separately, embodiments of the invention may be integrated into the system(s) with which they are associated. All the embodiments of the invention disclosed herein can be made and used without undue experimentation in light of the disclosure. Although the best mode of the invention contemplated by the inventor(s) is disclosed, embodiments of the invention are not limited thereto. Embodiments of the invention are not limited by theoretical statements (if any) recited herein. The individual steps of embodiments of the invention need not be performed in the disclosed manner, or combined in the disclosed sequences, but may be performed in any and all manner and/or combined in any and all sequences. The individual components of embodiments of the invention need not be formed in the disclosed shapes, or combined in the disclosed configurations, but could be provided in any and all shapes, and/or combined in any and all configurations. The individual components need not be fabricated from the disclosed materials, but could be fabricated from any and all suitable materials. Homologous replacements may be substituted for the substances described herein. Agents which are both chemically and physiologically related may be substituted for the agents described herein where the same or similar results would be achieved.

Various substitutions, modifications, additions and/or rearrangements of the features of embodiments of the invention may be made without deviating from the spirit and/or scope of the underlying inventive concept. All the disclosed elements and features of each disclosed embodiment can be combined with, or substituted for, the disclosed elements and features of every other disclosed embodiment except where such elements or features are mutually exclusive. The spirit and/or scope of the underlying inventive concept as defined by the appended claims and their equivalents cover all such substitutions, modifications, additions and/or rearrangements.

The appended claims are not to be interpreted as including means-plus-function limitations, unless such a limitation is explicitly recited in a given claim using the phrase(s) “means for” and/or “step for.” Subgeneric embodiments of the invention are delineated by the appended independent claims and their equivalents. Specific embodiments of the invention are differentiated by the appended dependent claims and their equivalents.

### REFERENCES

Rocchia, M; Rossi, A M; Borini, S; Boarino, L; Amato, G; Laser local oxidation of porous silicon: a FTIR spectroscopy investigation, PHYSICA STATUS SOLIDI A 202, 8, 1658-1661, 2005.
Fujiwara, M; Matsumoto, T; Kobayashi, H; Tanaka, K; Happo, N; Horii, K; Strong enhancement and long-time stabilization of porous silicon photoluminescence by laser irradiation, JOURNAL OF LUMINESCENCE 113, 34, 243-248, 2005.
Lysenko, V; Bidault, F; Alekseev, S; Zaitsev, V; Barbier, D; Turpin, C; Geobaldo, F; Rivolo, P; Garrone, E; Study of porous silicon nanostructures as hydrogen reservoirs, JOURNAL OF PHYSICAL CHEMISTRY B, 109, 42, 19711-19718, 2005.
Miotto, R; Srivastava, G P; Ferraz, A C; Methanol adsorption on silicon (001), SURFACE SCIENCE 575, 3, 287-299, 2005.
Niu, D; Ashcraft, R W; Parsons, G N; Water absorption and interface reactivity of yttrium oxide gate dielectrics on silicon, APPLIED PHYSICS LETTERS 80, 19, 3575-3577, 2002.
Fukuda, Y; Yu, YD; Zhou, W; Furuya, K; Suzuki, H; Quenching of porous silicon photoluminescence by ammonia hydrogen peroxide mixture, JOURNAL OF THE ELECTROCHEMICAL SOCIETY 147, 10, 3917-3921, 2000.
Ogata, Y H; Tsuboi, T; Sakka, T; Naito, S; Oxidation of porous silicon in dry and wet environments under mild temperature conditions, JOURNAL OF POROUS MATERIALS 7, 1-3, 63-66, 2000.
Salonen, J; Lehto, V P; Laine, E; The room temperature oxidation of porous silicon, APPLIED SURFACE SCIENCE 120, 3-4, 191-198, 1997.
Bateman, J E; Eagling, R D; Horrocks, B R; Houlton, A; Worrall, D R; Role for organic molecules in the oxidation of porous silicon, CHEMICAL COMMUNICATIONS 23, 2275-2276, 1997.
Bateman, J E; Horrocks, B R; Houlton, A, Reactions of water and methanol at hydrogen-terminated silicon surfaces studied by transmission FTIR, JOURNAL OF THE CHEMICAL SOCIETY-FARADAY TRANSACTIONS 93, 14, 2427-2431, 1997.
Kim, N Y; Laibinis, P E; Thermal derivatization of porous silicon with alcohols, JOURNAL OF THE AMERICAN CHEMICAL SOCIETY 119, 9, 2297-2298, 1997.
Mawhinney, D B; Glass, J A; Yates, J T; FTIR study of the oxidation of porous silicon, JOURNAL OF PHYSICAL CHEMISTRY B 101, 7, 1202-1206, 1997.
Salonen, J; Lehto, VP; Laine, E; Thermal oxidation of free-standing porous silicon films, APPLIED PHYSICS LETTERS 70, 5, 637-639, 1997.
Glass, J A; Wovchko, E A; Yates, J T; Reaction of Methanol with Porous Silicon, SURFACE SCIENCE 338, 1-3, 125-137, 1995.
Rehm, J M; McLendon, G L; Tsybeskov, L; Fauchet, P M; How Methanol Affects the Surface of Blue and Red Emitting Porous Silicon, APPLIED PHYSICS LETTERS 66, 26, 3669-3671, 1995.
Hory, M A; Herino, R; Ligeon, M; Muller, F; Gaspard, F; Mihalcescu, I; Vial, J C; Fourier-Transform IR Monitoring of Porous Silicon Passivation During Posttreatments Such as Anodic-Oxidation and Contact with Organic-Solvents, THIN SOLID FILMS 255, 1-2, 200-203, 1995.
Ehrley, W; Butz, R; Mantl, S; External Infrared Reflection Absorption-Spectroscopy of Methanol on an Epitaxially Grown SI(100)2×1 Surface, SURFACE SCIENCE 248, 1-2, 193-200, 1991.

What is claimed is:

1. A method, comprising
exposing a first portion of a porous silicon surface to actinic radiation to promote oxidation on the first portion of the porous silicon surface; and
exposing the porous silicon surface to an alcohol solvent to change the optical properties of a second portion of the porous silicon surface.

2. The method of claim 1, wherein the optical properties of the second portion of the porous silicon surface are substantially degraded.

3. The method of claim 1, wherein the changed optical properties of the second portion of the porous silicon surface includes a photonic stop-band that is narrowed, reduced in magnitude and shifted to shorter wavelengths compared to compared to its original spectral position.

4. The method of claim 1, wherein exposing the first portion of the porous silicon surface to actinic radiation includes photolithographically patterning the porous silicon surface.

5. The method of claim 1, wherein exposing the porous silicon surface to the alcohol solvent includes immersing the porous silicon surface in the alcohol solvent.

6. The method of claim 1, wherein the alcohol solvent includes at least one member selected from the group consisting of methanol and ethanol.

7. The method of claim 1, wherein the porous silicon surface is prepared by electrolyte etching.

8. An assembly, comprising an article of manufacture made by the method of claim 1.

9. A composition made by the method of claim 1.

12. A composition, comprising a porous silicon surface including
a first portion of the porous silicon surface; and
a second portion of the silicon surface, characterized by a second portion photonic stop-band that is narrowed, reduced in magnitude and shifted to shorter wavelengths compared to a spectral position of a first portion photonic stop-band.

13. The composition of claim 12, wherein the first portion of the porous silicon surface is prepared by exposing the first portion of a porous silicon surface to actinic radiation to promote oxidation on the first portion of the porous silicon surface and the second portion of the porous is prepared by exposing the porous silicon surface to an alcohol solvent to change the optical properties of the second portion of the porous silicon surface.

14. A heterostructure comprising the composition of claim 12.

15. A photonic crystal comprising the composition of claim 12.
